(19) United States
(12) Patent Application Publication
(10) Pub. No.: US 2009/0065050 A1
(43) Pub. Date: Mar. 12, 2009

(54) Method and structure for textured thermal cut for photovoltaic applications for thin films

(75) Inventors: Nathan W. Cheung, Hong Kong (CN); Man Wong, Hong Kong (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silicon China (HK) Limited, Hong Kong (CN)

(21) Appl. No.: 12/204,590

(22) Filed: Sep. 4, 2008

Related U.S. Application Data
(60) Provisional application No. 60/971,517, filed on Sep. 11, 2007.

(51) Int. Cl. H01L 31/00; H01L 21/00

(52) U.S. Cl. 136/256; 438/68; 257/E21.001

(57) ABSTRACT

A photovoltaic device and related methods of manufacture. The device has a support substrate having a support surface region. The device has a thickness of crystalline material overlying the support surface region of the support substrate. Preferably, the thickness of material has an upper surface region. The device has a glue layer provided between the support surface region and the thickness of material according to a specific embodiment. In a preferred embodiment, the device has a textured surface region formed overlying from the upper surface region of the thickness of crystalline material. Depending upon the embodiment, the device has a plurality of elevated regions having a first thickness defining a first portion of the textured surface region and a plurality of recessed regions having a second thickness defining a second portion of the textured surface region.

### CROSS-REFERENCES TO RELATED APPLICATIONS

This application claims priority to U.S. Provisional Application No. 60/971,517 filed Sep. 11, 2007, which is incorporated by reference herein for all purposes.

### BACKGROUND OF THE INVENTION

The present invention relates generally to solar energy techniques. In particular, the present invention provides a method and resulting device fabricated from a thermal separation process to form a textured region for photovoltaic applications. More particularly, the present invention provides a method and resulting device for manufacturing the photovoltaic regions with improved light trapping capabilities overlying a substrate member. Such substrate member can be a support member, such as a low grade polysilicon plate, metal plate, glass plate, a combination of these, or the like. Merely by way of example, the invention has been applied to solar panels, commonly termed modules, but it would be recognized that the invention has a much broader range of applicability.

Greenhouse gases are evolving a rapid rate, leading to global warming. As the population of the world increases rapidly to over six billion people, there has been an equally large consumption of energy resources, which leads to additional greenhouse gases. Often times, conventional energy comes from fossil fuels, including oil and coal, hydroelectric plants, nuclear sources, and others. As merely an example, further increases in oil consumption have been projected. Developing nations such as China and India account for most of the increase, although the United States remains the biggest consumer of energy resources. In the U.S., almost every aspect of our daily lives depends, in part, on oil. These aspects include driving to and from work, heating our homes, and operating large machines for construction and the like.

Oil is becoming increasingly scarce. As time further progresses, an era of “cheap” and plentiful oil is coming to an end. Oil will eventually disappear, which could possibly take us back to primitive times. Accordingly, other and alternative sources of energy have been developed. Modern day society has also relied upon other very useful sources of energy. Such other sources of energy include hydroelectric, nuclear, and the like to provide our electricity needs. Such electricity needs range from lighting our buildings and homes to operating computer systems and other equipment and the like. Most of our conventional electricity requirements for these home and business uses come from turbines run on coal or other forms of fossil fuel, nuclear power generation plants, and hydroelectric plants, as well as other forms of renewable energy. A popular form of renewable energy has been solar, which is derived from our sun.

Our sun is essential for solar energy. Solar energy possesses many desired characteristics. As noted above, solar energy is renewable. Solar energy is also abundant and clean. Conventional technologies developed often capture solar energy, concentrate it, store it, and convert it into other useful forms of energy. A popular example of one of these technologies includes solar panels. Such solar panels include solar cells that are often made using silicon bearing materials, such as polysilicon or single crystal silicon. An example of such solar cells can be manufactured by various companies that span our globe. Such companies include, among others, Q Cells in Germany, Sun Power Corporation in California, Suntech of China, and Sharp in Japan. Other companies include BP Solar and others.

Unfortunately, solar cells still have limitations although solar panels have been used successfully for certain applications. As an example, solar cells are often costly. Solar cells are often composed of silicon bearing wafer materials, which are difficult to manufacture efficiently on a large scale. Availability of solar cells made of silicon is also somewhat scarce with limited silicon manufacturing capacities. These and other limitations are described throughout the present specification, and may be described in more detail below.

From the above, it is seen that techniques for improving solar devices is highly desirable.

### BRIEF SUMMARY OF THE INVENTION

According to the present invention, techniques related to solar energy are provided. In particular, the present invention provides a method and resulting device fabricated from a thermal separation process to form a textured region for photovoltaic applications. More particularly, the present invention provides a method and resulting device for manufacturing the photovoltaic regions with improved light trapping capabilities overlying a substrate member. Such substrate member can be a support member, such as a low grade polysilicon plate, metal plate, glass plate, a combination of these, or the like. Merely by way of example, the invention has been applied to solar panels, commonly termed modules, but it would be recognized that the invention has a much broader range of applicability.

In a specific embodiment, the present invention provides a method for fabricating a photovoltaic material. The method includes providing a semiconductor substrate including a surface region and forming a blocking layer (e.g., mask, block, photo mask) overlying the surface region. In a specific embodiment, the blocking layer includes a plurality of opened regions, which exposes portions of the surface region. In a specific embodiment, the method includes forming a patterned cleave region using an co-implant process including hydrogen species by subjecting at least the hydrogen species to the plurality of exposed regions to define a thickness of material to be detached, which is provided between the surface region and the patterned cleave region. In a specific embodiment, the method removes the blocking layer. In a specific embodiment, the method joins the surface region of the semiconductor substrate via a glue layer to a support surface region of a support substrate. In a specific embodiment, the method includes delaminating the thickness of material from a remaining portion of the semiconductor substrate, while the thickness of material remains attached to the support substrate. In a specific embodiment, the method includes forming a textured surface region associated with the patterned cleave region occupying a plane parallel to an entirety of the surface region provided from a portion of the thickness of material. Preferably, the method includes using the thickness of material attached to the support substrate for a photovoltaic application.

In an alternative specific embodiment, the present invention provides a method for fabricating a photovoltaic material. The method includes providing a semiconductor substrate including a surface region. In a specific embodiment, the method includes introducing a plurality of particles through the surface region, using at least an implant process, to form a patterned cleave region associated with an entirety of a plane parallel to the surface region to define a thickness of material to be detached. In a preferred embodiment, the thickness of material is provided between the surface region and the patterned cleave region. The method joins the surface region of the semiconductor substrate via a glue layer to a support surface region of a support substrate. In a specific embodiment, the method delaminates the thickness of material from a remaining portion of the semiconductor substrate, while the thickness of material remains attached to the support substrate. In a specific embodiment, the method forms a textured surface region associated with the patterned cleave region provided from a portion of the thickness of material during delamination and/or other process. The method uses the thickness of material attached to the support substrate for a photovoltaic application.

In yet an alternative specific embodiment, the present invention provides a photovoltaic device. The device has a support substrate having a support surface region. The device has a thickness of crystalline material overlying the support surface region of the support substrate. Preferably, the thickness of material has an upper surface region. The device has a glue layer provided between the support surface region and the thickness of material according to a specific embodiment. In a preferred embodiment, the device has a textured surface region formed overlying from the upper surface region of the thickness of crystalline material. Depending upon the embodiment, the device has a plurality of elevated regions having a first thickness defining a first portion of the textured surface region and a plurality of recessed regions having a second thickness defining a second portion of the textured surface region.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a hydrogen co-implant to form a thin layer of photovoltaic material. Since the layers are very thin, multiple layers of photovoltaic regions can be formed from a single conventional single crystal silicon or other like material wafer. In a preferred embodiment, the present thin layer removed by hydrogen implant and thermal treatment can be provided on a low grade substrate material, which will serve as a support member. In a preferred embodiment, the present technique can also be provided to form a textured surface that allows for a longer light path, which allows for more efficient light trapping for photovoltaic applications. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1 through 8 are simplified diagrams illustrating a method for fabricating a photovoltaic material having a textured surface according to an embodiment of the present invention; and

FIGS. 9 through 10 are simplified diagrams illustrating experimental results derived from a method for fabricating a photovoltaic material according to an embodiment of the present invention.

### DETAILED DESCRIPTION OF THE INVENTION

According to the present invention, techniques related to solar energy are provided. In particular, the present invention provides a method and resulting device fabricated from a thermal separation process to form a textured region for photovoltaic applications. More particularly, the present invention provides a method and resulting device for manufacturing the photovoltaic regions with improved light trapping capabilities overlying a substrate member. Such substrate member can be a support member, such as a low grade polysilicon plate, metal plate, glass plate, a combination of these, or the like. Merely by way of example, the invention has been applied to solar panels, commonly termed modules, but it would be recognized that the invention has a much broader range of applicability.

### General Method Embodiment

In a specific embodiment, the present invention provides a method for fabricating a photovoltaic device that can be outlined as follows:

1. Provide a semiconductor substrate, e.g., single crystal silicon, silicon germanium, Group II/VI, Group III/V;

2. Form a blocking layer (e.g., mask, block, photo mask) including a plurality of opened regions overlying the surface region of the semiconductor substrate;

3. Forming a patterned cleave region using an co-implant process including hydrogen species by subjecting at least the hydrogen species to the plurality of opened regions to define a thickness of material to be detached, which is provided between the surface region and the patterned cleave region;

4. Remove the blocking layer;

5. Join the surface region of the semiconductor substrate via a glue layer to a support surface region of a support substrate;

6. Delaminate the thickness of material from a remaining portion of the semiconductor substrate;

7. Maintain attachment of the thickness of material to the support substrate during step (6);

8. Form a textured surface region associated with the patterned cleave region occupying an entirety of plane parallel to an entirety of the surface region provided from a portion of the thickness of material;

9. Use the thickness of material attached to the support substrate for a photovoltaic application; and

10. Perform other steps, as desired.

The above sequence of steps provides a method for fabricating a textured surface region for photovoltaic applications according to an embodiment of the present invention. As shown, the method uses a combination of steps including a way of forming a thickness of material, which will be detached according to a specific embodiment. Other alternatives can also be provided where steps are added, one or more steps are removed, or one or more steps are provided in a different sequence without departing from the scope of the claims herein. Further details of the present method can be found throughout the present specification and more particularly below.

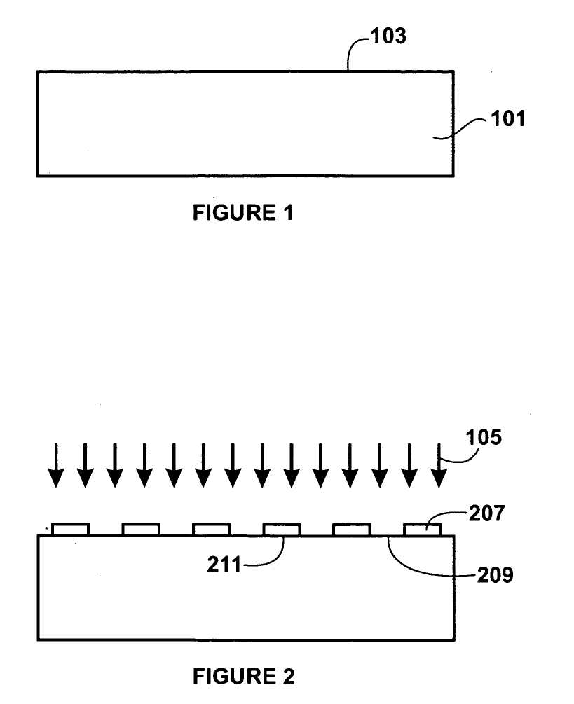

FIGS. 1 through 8 are simplified diagrams illustrating a method for fabricating a photovoltaic material according to an embodiment of the present invention. These diagrams are merely examples, which should not unduly limit the scope of the claims herein. One of ordinary skill in the art would recognize many variations, modifications, and alternatives. In a specific embodiment, the present invention provides a method for fabricating a photovoltaic material. As shown in FIG. 1, the method includes providing a semiconductor substrate 101, which includes surface region 103. As an example, the material can be single crystal silicon, silicon germanium, gallium arsenide, Group II/VI, or Group III/IV materials. Alternatively, the material can be composites, layered, graded, or others, depending upon the specific embodiment. Of course, there can be other variations, modifications, and alternatives.

Referring to FIG. 2, the method includes forming a blocking layer 207 overlying the surface region. In a specific embodiment, the blocking layer can be a hard mask, a blocking mask, or photosensitive material, such as photoresist or the like. In a specific embodiment, the blocking layer includes a plurality of opened regions 209. Such opened regions are separated by blocking layer 211 according to a specific embodiment. Depending upon the embodiment, the blocking layer can be patterned as a plurality of parallelograms, triangular shaped regions, annular regions, or other shapes, including sizes and the like. Of course, there can be other variations, modifications, and alternatives.

In a specific embodiment, the method includes subjecting 105 the exposed regions of the thickness of material to a hydrogen species as illustrated by FIG. 2. In a specific embodiment, other species can also be used to replace hydrogen or be used in combination with hydrogen. In a specific embodiment, the hydrogen species can be introduced using an implantation process such as beam line implantation, plasma immersion ion implantation, ion shower, or other techniques depending upon the application. Of course, there can be other variations, modifications, and alternatives.

Using hydrogen as an example, such hydrogen can be implanted using selected doses and energies. Of course, there can be other variations, modifications, and alternatives.

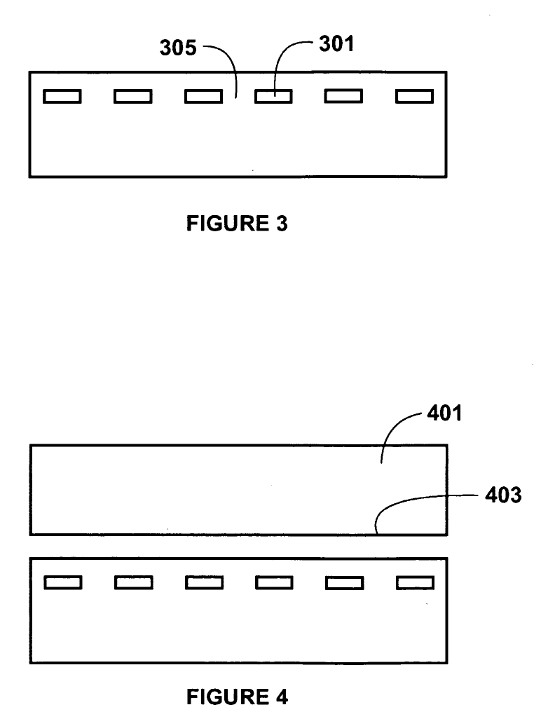

Referring now to FIG. 3, the present method forms a plurality of implanted regions 301 separated from non-implanted regions 305 to form a cleave region. In a specific embodiment, the cleave region is patterned, which includes a plurality of implanted regions and a plurality of non-implanted regions. In a specific embodiment, the patterned cleave region comprises a plurality of first regions having a hydrogen concentration and a plurality of second regions free from a hydrogen concentration. In a preferred embodiment, the implant process comprises a first implant process and a second implant process to form a co-implant process, which may be a sequential implant process. Of course, there can be other variations, modifications, and alternatives.

In a specific embodiment, the method includes providing a glue layer overlying a surface region of the thickness of material. Depending upon the embodiment, the glue layer can be provided on a surface region 403 of a support member 401 or surface region of the thickness of material on the substrate. In a specific embodiment, the glue layer is selected from spin on glass, a eutectic material, a polymer, or a metal layer. Of course, there can be other variations, modifications, and alternatives.

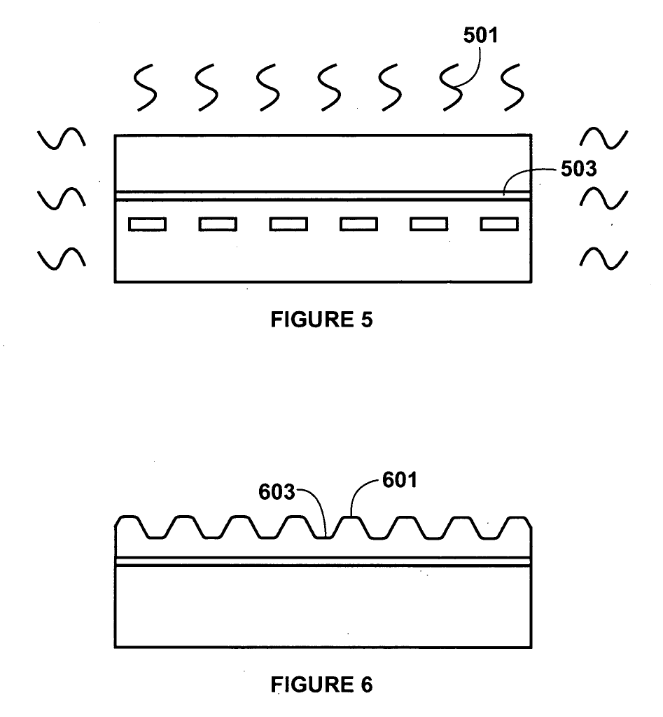

In a specific embodiment, the method joins the surface region of the thickness of material via the glue layer 503 to the support substrate, as shown in FIG. 5. In a specific embodiment, the support substrate can be a metal, dielectric, or semiconductor, or any combination of these. The support substrate can also be an organic polymer material, composite, or other structural entity according to a specific embodiment. As merely an example, the metal can be stainless steel, aluminum, etc., including oxides of these metals. As merely an example, the dielectric material can be glass, quartz, organic polymer, or others. As merely an example, the semiconductor can be silicon, including amorphous silicon, polysilicon, metallurgical silicon, and other forms of silicon. Of course, there can be other variations, modifications, and alternatives.

In a preferred embodiment, the method includes delaminating 501 a portion of the thickness of material from the semiconductor substrate as also illustrated in FIG. 5. In a specific embodiment, delamination occurs using thermal, chemical, mechanical, gravitational, electromagnetic, or other energy sources, including combinations of such sources. In a preferred embodiment, delamination occurs using thermal treatment by subjecting the bonded structure to a predetermined temperature for a period if time to cause release at the cleave region from the remaining substrate portion, as shown. As shown, the delamination occurs while the portion of the thickness of material remains attached to the support substrate, to cause formation of a textured surface region 601, 603 from the portion of the thickness of the material as illustrated by FIG. 6. Of course, there can be other variations, modifications, and alternatives.

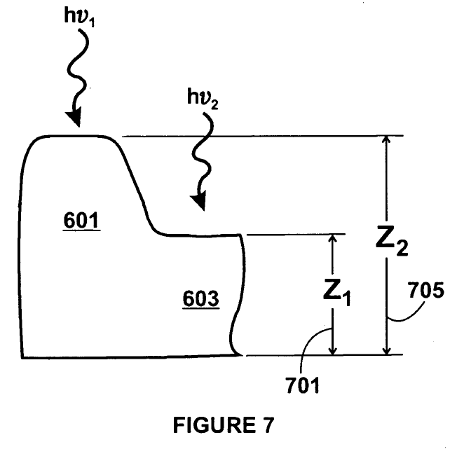

In a specific embodiment in reference to FIG. 7, a textured surface region 601 603 is formed from a detached surface region of the thickness of material. In a specific embodiment, the textured surface region has a roughness. Depending upon the embodiment, the textured surface region is characterized by a surface roughness to facilitate capture of one or more photons being illuminated thereon. In other words, the textured surface region has a surface roughness to cause reflection from a total amount of irradiating in certain frequencies. Of course, there can be other variations, modifications, and alternatives.

In a preferred embodiment, the textured surface region is characterized by a plurality of recessed regions surrounded by an elevated region to form the textured surface region. Alternatively, the textured surface region is characterized by a plurality of elevated regions surrounded by a recessed region to form the textured surface region. In a preferred embodiment, the elevated region provides a thicker material portion than a thickness associated with the implanted cleave region. In a preferred embodiment, the thicker material portion provides a longer path for electromagnetic radiation to traverse, which leads to improved capture of photons. As shown, thickness 601 is characterized by thickness z2 705 and thickness 603, which corresponds to the implanted region, is characterized by z1 701. As shown, z1 is less than z2 in a specific embodiment. Of course, there can be other variations, modifications, and alternatives.

As shown, the above sequence of steps provides a method for fabricating a textured surface region for photovoltaic applications according to an embodiment of the present invention. As shown, the method uses a combination of steps including a way of forming a thickness of material, which will be detached according to a specific embodiment. Other alternatives can also be provided where steps are added, one or more steps are removed, or one or more steps are provided in a different sequence without departing from the scope of the claims herein. Further details of the present method and resulting device can be found throughout the present specification and more particularly below.

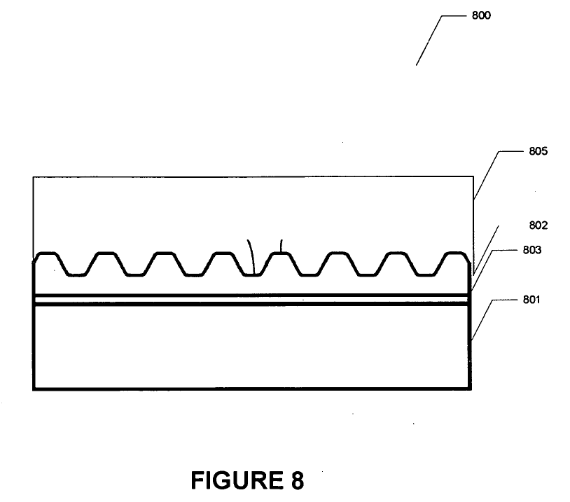

FIG. 8 is a simplified diagram of a photovoltaic device 800 according to an embodiment of the present invention. This diagram is merely an example, which should not unduly limit the scope of the claims herein. One of ordinary skill in the art would recognize many variations, modifications, and alternatives. As shown is a based material for the photovoltaic device. The device has a support substrate 801 having a support surface 802 region. In a specific embodiment, the support substrate can be a metal, dielectric, or semiconductor, or any combination of these. The support substrate can also be an organic polymer material, composite, or other structural entity according to a specific embodiment. As merely an example, the metal can be stainless steel, aluminum, or others, including oxides of these metals. As merely an example, the dielectric material can be glass, quartz, organic polymer, or others. As merely an example, the semiconductor can be silicon, including amorphous silicon, polysilicon, metallurgical silicon, and other forms of silicon. Of course, there can be other variations, modifications, and alternatives.

In a specific embodiment, the device has a thickness of semiconductor material 805 characterized by a textured surface region overlying the support surface region of the support substrate. In a specific embodiment, the semiconductor material is a single crystal semiconductor material, which will serve as a base material for a photovoltaic device. As an example, the material can be single crystal silicon, silicon germanium, gallium arsenide, Group II/VI, or Group III/IV materials. Alternatively, the material can be composites, layered, graded, or others, depending upon the specific embodiment. Of course, there can be other variations, modifications, and alternatives.

Referring again to FIG. 8, the device has a glue layer 803 provided between the support surface region and the thickness of material. In a specific embodiment, the glue layer is selected from spin on glass, a eutectic material, a polymer, or a metal layer. Of course, there can be other variations, modifications, and alternatives.

In a specific embodiment, the textured surface region has a roughness. Depending upon the embodiment, the textured surface region is characterized by a surface roughness to facilitate capture of one or more photons being illuminated thereon. In other words, the textured surface region has a surface roughness that causes reflection from a total amount of irradiating in a frequency. Of course, there can be other variations, modifications, and alternatives.

In a preferred embodiment, the textured surface region is characterized by a plurality of recessed regions surrounded by an elevated region to form the textured surface region. Alternatively, the textured surface region is characterized by a plurality of elevated regions surrounded by a recessed region to form the textured surface region. In a preferred embodiment, the elevated region provides a thicker material portion than a thickness associated with the implanted cleave region. In a preferred embodiment, the thicker material portion provides a longer path for electromagnetic radiation to traverse, which leads to improved capture of photons. Of course, there can be other variations, modifications, and alternatives.

In a specific embodiment, the device also has active regions, including P-type and N-type regions. In a specific embodiment, the device also has contacts and metallization, which serve as electrodes. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims. Further details of experimental techniques according to embodiments of the present invention are provided throughout the present specification and more particularly below.

### EXAMPLES

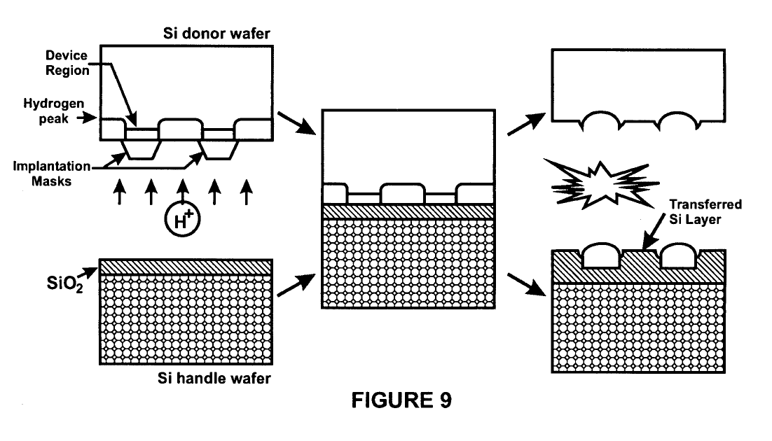

To prove the principles and operation of the present invention, we have performed experiments. These experiments are merely examples, which should not unduly limit the scope of the claims herein. One of ordinary skill in the art would recognize many variations, modifications, and alternatives. These experiments are merely for purposes of demonstrating the texturing process in accordance with the present invention. Referring To FIG. 9, we have provided a simplified set of diagrams illustrating our experiment.

As shown, we provided a method for fabricating a photovoltaic material. As shown, the method includes providing a single crystal silicon semiconductor substrate, which includes surface region. The substrate included a blocking layer overlying the surface region. In a specific embodiment, the blocking layer was photosensitive material that included a plurality of opened regions. Such opened regions are separated by blocking layer according to a specific embodiment. We subjecting the exposed regions of the thickness of material to a hydrogen implant, although other species can also be used to replace hydrogen or be used in combination with hydrogen. Using hydrogen as an example, such hydrogen can be implanted using selected doses and energies.

As shown, the present method forms a plurality of implanted regions separated from non-implanted regions to form a cleave region. We provided a glue layer of silicon dioxide overlying a surface region of a support member, which was a silicon handle wafer. We joined the surface region of the thickness of material via the glue layer to the support substrate. Thermal treatment was used to improve bonding between the support member and the thickness of material on the substrate. Of course, there can be other variations, modifications, and alternatives.

Next, we delaminated a portion of the thickness of material from the semiconductor substrate using a thermal treatment process. The thermal treatment process used a temperature of about 500 Degrees Celsius, but can be others. As shown, the delamination occurs while the portion of the thickness of material remains attached to the support substrate, to cause formation of a textured surface region from the portion of the thickness of the material as also illustrated. The textured surface region is characterized by a plurality of elevated regions surrounded by a recessed region to form the textured surface region. The elevated region provides a thicker material portion than a thickness associated with the implanted cleave region. The thicker material portion provides a longer path for electromagnetic radiation to traverse, which leads to improved capture of photons. Of course, there can be other variations, modifications, and alternatives.

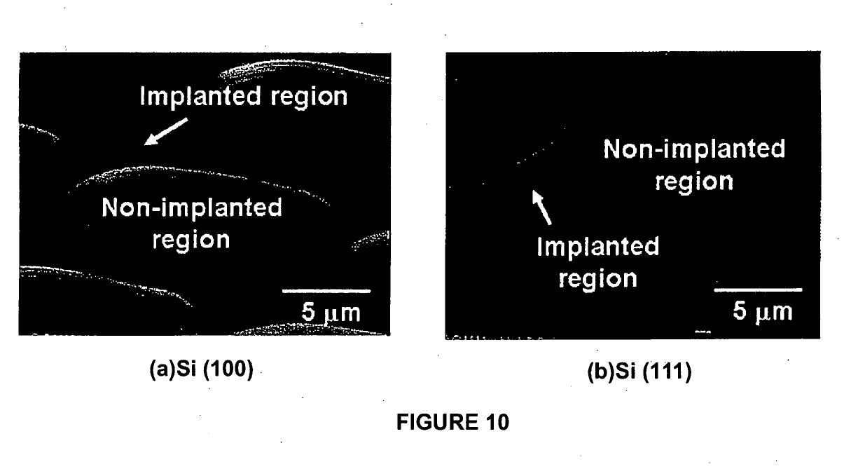

Referring to FIG. 10, we have prepared photographs using a scanning electron microscopy technique. As shown, we prepared SEM micrographs of fractured surfaces of silicon (100) and silicon (111) from a patterned hydrogen-implanted silicon substrate using thermal delamination. The hydrogen implantation was done at 180 keV with a dose of 8×10¹⁶ ions/cm². The mask pattern is parallelogram with fractional implantation area of 36%. With a silicon (111) substrate, the transferred surface toward the non-implanted region is flatter. For silicon (100), the cleavage is consistently kinked upward from the boundary between non-implanted and implanted regions. Of course, there can be other variations, modifications, and alternatives.

As shown, the above sequence of steps provides a method for fabricating a textured surface region for photovoltaic applications according to an embodiment of the present invention. As shown, the method uses a combination of steps including a way of forming a thickness of material, which will be detached according to a specific embodiment. Other alternatives can also be provided where steps are added, one or more steps are removed, or one or more steps are provided in a different sequence without departing from the scope of the claims herein. Further details of the present method and resulting device can be found throughout the present specification and more particularly below.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for fabricating a photovoltaic material, the method comprising:
providing a semiconductor substrate including a surface region;
forming a blocking layer overlying the surface region, the blocking layer including a plurality of opened regions;
forming a patterned cleave region using an co-implant process including hydrogen species by subjecting at least the hydrogen species to the plurality of opened regions to define a thickness of material to be detached, the thickness of material being provided between the surface region and the patterned cleave region;
removing the blocking layer;
joining the surface region of the semiconductor substrate via a glue layer to a support surface region of a support substrate;
delaminating the thickness of material from a remaining portion of the semiconductor substrate, while the thickness of material remains attached to the support substrate; and
forming a textured surface region associated with the patterned cleave region occupying a plane parallel to an entirety of the surface region provided from a portion of the thickness of material; and
using the thickness of material attached to the support substrate for a photovoltaic application.

2. The method of claim 1 wherein the semiconductor substrate comprises silicon.

3. The method of claim 1 wherein the semiconductor substrate comprises single crystal silicon, silicon germanium, gallium arsenide, Group II/VI, or Group III/IV materials.

4. The method of claim 1 wherein the blocking layer comprises a hard mask.

5. The method of claim 1 wherein the blocking layer comprises a photosensitive material.

6. The method of claim 1 wherein the blocking layer is an implant mask.

7. The method of claim 1 wherein the removing the blocking layer comprises stripping or ashing.

8. The method of claim 1 wherein the patterned cleave region comprises a plurality of first regions having a hydrogen concentration and a plurality of second regions free from a hydrogen concentration.

9. The method of claim 1 wherein the co-implant process comprises the hydrogen species and a helium species.

10. The method of claim 1 wherein the co-implant process is a sequential implant process.

11. The method of claim 1 wherein the delaminating comprises subjecting the thickness of material to a thermal treatment process.

12. The method of claim 1 wherein the delaminating comprises subjecting the thickness of material to a mechanical prying process.

13. The method of claim 1 wherein the delaminating comprises subjecting the thickness of material to electromagnetic radiation.

14. The method of claim 1 wherein the delaminating comprises subjecting the thickness of material to a chemical process.

15. The method of claim 1 wherein the delaminating comprises subjecting the thickness of material to an energy to cause the delaminating.

16. The method of claim 1 wherein the glue layer is selected from spin on glass, a eutectic material, a polymer, or a metal layer.

17. The method of claim 1 wherein the textured surface region is characterized by a plurality of recessed regions surrounded by an elevated region to form the textured surface region.

18. The method of claim 1 wherein the textured surface region is characterized by a plurality of elevated regions surrounded by a recessed region to form the textured surface region.

19. The method of claim 1 wherein the using comprising forming one or more P type and N type junctions on a portion of the crystalline material.

20. A method for fabricating a photovoltaic material, the method comprising:
providing a semiconductor substrate including a surface region;
introducing a plurality of particles through the surface region, using at least an implant process, to form a patterned cleave region associated with an entirety of a plane parallel to the surface region to define a thickness of material to be detached, the thickness of material being provided between the surface region and the patterned cleave region;
joining the surface region of the semiconductor substrate via a glue layer to a support surface region of a support substrate;
delaminating the thickness of material from a remaining portion of the semiconductor substrate, while the thickness of material remains attached to the support substrate; and
forming a textured surface region associated with the patterned cleave region provided from a portion of the thickness of material; and
using the thickness of material attached to the support substrate for a photovoltaic application.

21. The method of claim 20 wherein the semiconductor substrate comprises silicon.

22. The method of claim 20 wherein the semiconductor substrate comprises single crystal silicon, silicon germanium, gallium arsenide, Group II/VI, or Group III/IV materials.

23. The method of claim 20 wherein the patterned cleave region is provided by blocking layer comprises a hard mask.

24. The method of claim 20 wherein the patterned cleave region is provided by blocking layer comprises a photosensitive material.

25. The method of claim 20 wherein the patterned cleave region is provided by blocking layer is an implant mask.

26. The method of claim 20 wherein the patterned cleave region comprises a plurality of implanted regions and a plurality of non-implanted regions.

27. The method of claim 20 wherein the patterned cleave region comprises a plurality of first regions having a hydrogen concentration and a plurality of second regions free from a hydrogen concentration.

28. The method of claim 20 wherein the implant process comprises a first implant process and a second implant process to form a co-implant process.

29. The method of claim 28 wherein the co-implant process is a sequential implant process.

30. The method of claim 20 wherein the delaminating comprises subjecting the thickness of material to a thermal treatment process.

31. The method of claim 20 wherein the delaminating comprises subjecting the thickness of material to a mechanical prying process.

32. The method of claim 20 wherein the delaminating comprises subjecting the thickness of material to electromagnetic radiation.

33. The method of claim 20 wherein the delaminating comprises subjecting the thickness of material to a chemical process.

34. The method of claim 20 wherein the delaminating comprises subjecting the thickness of material to an energy to cause the delaminating.

35. The method of claim 20 wherein the glue layer is selected from spin on glass, a eutectic material, a polymer, or a metal layer.

36. The method of claim 20 wherein the textured surface region is characterized by a plurality of recessed regions surrounded by an elevated region to form the textured surface region.

37. The method of claim 20 wherein the textured surface region is characterized by a plurality of elevated regions surrounded by a recessed region to form the textured surface region.

38. The method of claim 20 wherein the using comprising forming one or more P type and N type junctions on a portion of the crystalline material.

39. A photovoltaic device comprising:
a support substrate having a support surface region;
a thickness of crystalline material overlying the support surface region of the support substrate, the thickness of material having an upper surface region;
a glue layer provided between the support surface region and the thickness of material;
a textured surface region formed overlying from the upper surface region of the thickness of crystalline material;
a plurality of elevated regions having a first thickness defining a first portion of the textured surface region; and
a plurality of recessed regions having a second thickness defining a second portion of the textured surface region.

40. The device of claim 39 wherein the semiconductor substrate comprises silicon.

41. The device of claim 39 wherein the semiconductor substrate comprises single crystal silicon, silicon germanium, gallium arsenide, Group II/VI, or Group III/IV materials.

42. The device of claim 39 wherein the glue layer is selected from spin on glass, a eutectic material, a polymer, or a metal layer.

43. The device of claim 39 wherein the plurality of elevated regions is surrounded by the recessed regions.

44. The device of claim 39 wherein the plurality of recessed region is surrounded by the elevated regions.

45. The device of claim 39 wherein the support substrate comprises metallurgical polysilicon.

46. The device of claim 39 wherein the support substrate comprises glass or quartz.

47. The device of claim 39 wherein the support substrate comprises an organic material, a metal material, a dielectric material, or a semiconductor material.

48. The device of claim 39 further comprising one or more P type and N type junctions on a portion of the thickness of material.
